(19) United States
(12) Patent Application Publication
(10) Pub. No.: US 2017/0025306 A1
(43) Pub. Date: Jan. 26, 2017

(54) METHODS FOR PREPARING LAYERED SEMICONDUCTOR STRUCTURES AND RELATED BONDED STRUCTURES

(71) Applicant: SunEdison Semiconductor Limited (UEN201334164H), Singapore (SG)

(72) Inventors: Gang Wang, Grover, MO (US); Jeffrey L. Libbert, O'Fallon, MO (US); Qingmin Liu, Glen Carbon, IL (US); Alex Usenko, O'Fallon, MO (US); Shawn George Thomas, Chesterfield, MO (US)

(73) Assignee: SunEdison Semiconductor Limited (UEN201334164H), Singapore (SG)

(21) Appl. No.: 15/191,975

(22) Filed: Jun. 24, 2016

Related U.S. Application Data
(60) Provisional application No. 62/195,088, filed on Jul. 21, 2015.

(51) Int. Cl. H01L 21/762; C30B 29/06; C30B 1/02; H01L 21/02; H01L 29/06

(52) U.S. Cl. CPC H01L 21/76251; H01L 21/02532; H01L 21/02592; H01L 21/02667; H01L 29/0649; H01L 21/0262; C30B 1/023; C30B 29/06

(57) ABSTRACT

Methods for preparing silicon-on-insulator structures and related intermediate structures are disclosed. In some embodiments, a single crystal silicon seed crystal is bonded to an amorphous silicon layer disposed on a substrate and the amorphous layer is crystallized to form a monocrystalline silicon layer.

### CROSS-REFERENCE TO RELATED APPLICATION

This application claims the benefit of U.S. Provisional Application No. 62/195,088, filed Jul. 21, 2015, which is incorporated herein by reference in its entirety.

### FIELD OF THE DISCLOSURE

The field of the disclosure relates to methods for preparing layered semiconductor structures and related intermediate structures. In some embodiments, a single crystal silicon seed crystal is bonded to an amorphous silicon layer disposed on a substrate and the amorphous layer is crystallized to form a monocrystalline silicon layer.

### BACKGROUND

Multi-layered structures comprising a device layer with a device quality surface and a supporting substrate are useful for a number of different purposes. Multi-layered structures comprising a device quality layer bonded to a substrate may be fabricated or manufactured in a number of ways. For example, a multi-layered structure may be formed in which a donor wafer is bonded to a handle wafer with a dielectric layer such as silicon dioxide disposed between the donor wafer and handle wafer. The donor wafer may be ground, etched or cleaved to leave a relatively thin device layer on the dielectric layer. Other processes involve direct layer transfer in which an implanted wafer is bonded directly to the substrate, subjected to a low temperature anneal, and cleaved thermally and/or mechanically to result in a thin layer on the surface of the substrate.

A need exists for methods for producing high quality multi-layered structures at reduced cost. A need also exits for production methods that are capable of producing a device-quality silicon surface layer on silicon as well as on alien substrates such as quartz, sapphire and ceramics.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect of the present disclosure is directed to a method for preparing a layered semiconductor structure having a monocrystalline silicon device layer. An amorphous silicon layer is deposited on a substrate. The amorphous silicon layer and substrate form an amorphous layer-substrate interface. A single crystal silicon seed wafer is bonded on the amorphous silicon layer to form a bonded structure. The single crystal silicon seed wafer and amorphous silicon layer form a seed-amorphous layer interface. The bonded structure is annealed to crystallize the amorphous silicon layer and generate a monocrystalline silicon device layer from the amorphous silicon layer. The bonded structure is cleaved to separate the single crystal silicon seed wafer from the bonded structure and form a layered product structure comprising the substrate and the monocrystalline silicon device layer.

Another aspect of the present disclosure is directed to a bonded structure having a substrate selected from the group consisting of a silicon wafer, quartz, sapphire, ceramics, glass, germanium, silicon germanium, gallium nitride and aluminum nitride. The structure includes a single crystal silicon seed wafer and an amorphous silicon layer disposed between the substrate and the single crystal silicon seed wafer. The amorphous silicon layer and substrate form an amorphous layer-substrate interface. The single crystal silicon seed wafer and amorphous silicon layer forming a seed-amorphous layer interface.

Yet another aspect of the present disclosure is directed to a bonded structure. The bonded structure includes a substrate selected from the group consisting of a silicon wafer, quartz, sapphire, ceramics, glass, germanium, silicon germanium, gallium nitride and aluminum nitride. The structure includes a single crystal silicon seed wafer and a monocrystalline silicon device layer disposed between the substrate and the single crystal silicon seed wafer. The monocrystalline silicon device layer and substrate form a device layer-substrate interface. The single crystal silicon seed wafer and monocrystalline silicon device layer form a seed-device layer interface.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a schematic of a method to produce a layered semiconductor structure;

FIG. 2 is a cross-sectional, schematic drawing of a substrate for use in preparing the layered semiconductor structure;

FIG. 3 is a cross-sectional, schematic drawing of the substrate having an amorphous silicon layer deposited thereon;

FIG. 4 is cross-sectional, schematic drawing of a bonded structure resulting from bonding a seed wafer to the structure of FIG. 3;

FIG. 5 is cross-sectional, schematic drawing of a bonded structure after crystallizing the amorphous layer of the structure of FIG. 4; and

FIG. 6 is a cross-sectional, schematic drawing that shows separation of the seed wafer from the bonded structure of FIG. 5.

Corresponding reference characters indicate corresponding parts throughout the drawings.

### DETAILED DESCRIPTION

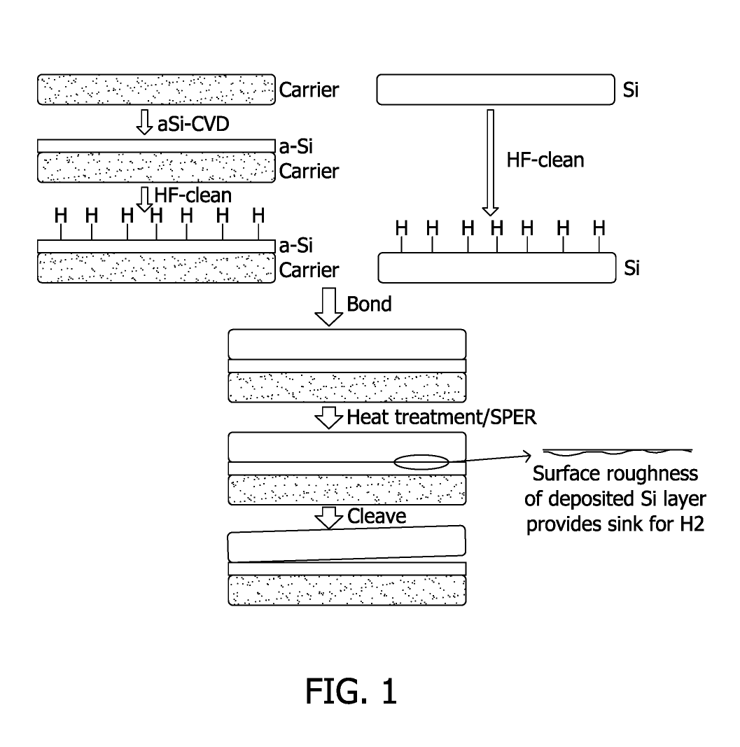

A method for producing a layered semiconductor structure according to embodiments of the present disclosure is schematically shown in FIG. 1. The layered semiconductor structure may be produced by depositing an amorphous silicon layer on a substrate. A single crystal silicon seed wafer is deposited on the amorphous silicon layer to form a bonded structure and the bonded structure is annealed to crystallize the amorphous silicon layer and generate a monocrystalline silicon layer from the amorphous silicon layer. The bonded structure is cleaved (e.g., autocleave upon cool down or mechanical cleave) to separate the single crystal silicon seed wafer from the bonded structure and form a layered product structure comprising the substrate and the monocrystalline silicon layer. The single crystal silicon seed wafer may be reused to produce additional layered structures. In such embodiments, process time and cost in preparing the multi-layered structure may be reduced.

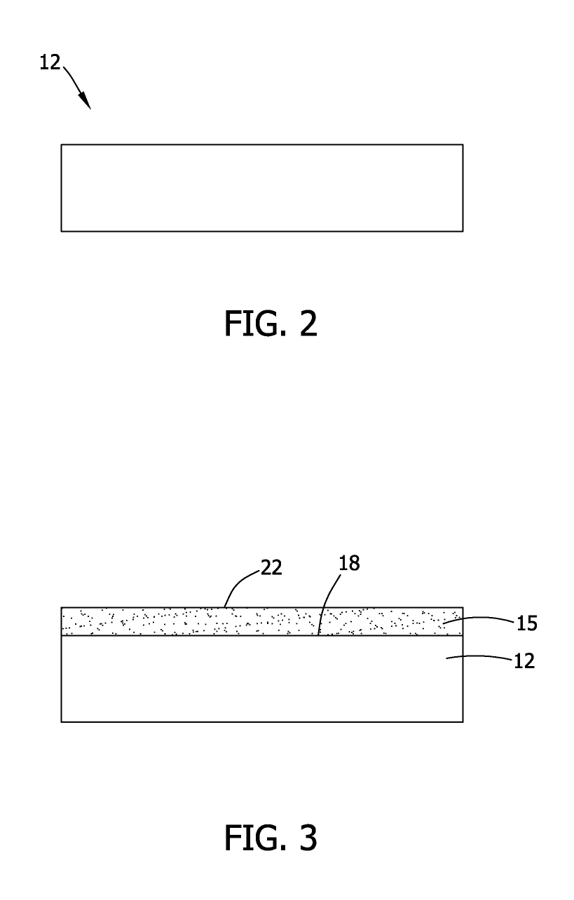

A substrate (or “carrier” or “handle”) 12 for use in accordance with the present disclosure is shown in FIG. 2. The substrate 12 may be selected from the group consisting of a silicon wafer, quartz, sapphire, ceramics (e.g., AlN, SiC or LiAlO₂), glass, germanium, silicon germanium, gallium nitride and aluminum nitride. In embodiments in which a silicon wafer is used as the substrate 12, the substrate 12 may be a single crystal silicon wafer and may be a single crystal silicon wafer which has been sliced from a single crystal ingot grown in accordance with conventional Czochralski crystal growing methods.

The substrate 12 (as well as the resulting layered semiconductor product structure and intermediate structures described herein) has a central axis, a front surface and a back surface that are generally perpendicular to the central axis. The substrate 12 includes a circumferential edge and a radius extending from the central axis to the circumferential edge. The substrate 12 may be any diameter suitable for use by those of skill in the art including, for example, 200 mm, 300 mm, greater than 300 mm or even 450 mm diameter substrates. In this regard, the additional layers, seed wafers and resulting layered semiconductor product structure described herein may have a diameter that corresponds to the diameter of the substrate 12 (i.e., 200 mm, 300 mm, greater than 300 mm or even 450 mm).

In some embodiments, the substrate 12 is a multi-layered structure (e.g., for formation of hybrid substrates such as Si(111)/oxide/Si(100) or Si(100)/oxide/Si(111) or for formation of RF devices from sapphire or ceramic substrates). The substrate 12 may include a base material such as a silicon wafer with an oxide layer on its surface (e.g., native oxide layer or deposited oxide layer).

In general, the substrate 12 (including any oxide layer or additional layers) may have any thickness capable of providing sufficient structural integrity to allow delamination of a bonded seed layer as described more fully below. The substrate 12 may have an average thickness of at least about 100 μm, typically at least about 200 μm and may have a thickness of from about 100 μm to about 900 μm, or even from about 500 μm to about 800 μm.

As shown in FIG. 3, an amorphous silicon layer 15 is deposited on the substrate 12. Such amorphous silicon (or “non-crystalline” silicon) does not include a well-ordered crystal lattice as with crystalline silicon. Rather, amorphous silicon is generally a continuous random network of bonds. Amorphous silicon may be distinguished from crystalline silicon by x-ray diffraction, Raman spectroscopy or other conventional characterization techniques. The amorphous silicon layer 15 and substrate 12 form an amorphous layer-substrate interface 18.

The amorphous silicon layer 15 may be deposited by chemical vapor deposition (CVD) or plasma enhanced CVD (PECVD) processes in which silicon is deposited from a silicon-containing gas. Suitable silicon-containing gases include silane (SiH₄), disilane (Si₂H₆), trisilane (Si₃H₈), pentasilane (Si₅H₁₂) or even higher orders of silane. The silicon-containing compound is typically introduced into the deposition reactor with a carrier gas such as hydrogen, nitrogen, argon or mixtures thereof.

The deposition reactor may be generally controlled to operate at a temperature sufficiently low to form amorphous silicon. The temperature at which the deposition occurs may range from about room temperature (about 25° C.) to about 580° C. with the particular temperature range depending on the particular silicon-containing gas used. For example, the reactor may operate from about 450° C. to about 580° C. for saline, from about 400° C. to about 580° C. for disilane, and from about 350° C. to about 580° C. for trisilane. PECVD processes may use reactor temperatures from about 100° C. to about 500° C. (regardless of silicon-containing gas). The pressure within the reactor (CVD or PECVD) may range from about 100 Pa (about 0.75 torr) to about 100 kPa (about 760 torr). Additional methods for depositing amorphous silicon include metalorganic chemical vapor deposition (MOCVD), physical vapor deposition (PVD), low pressure chemical vapor deposition (LPCVD) or molecular beam epitaxy (MBE).

Generally, the amorphous layer 15 has an amorphous structure upon deposition and is not rendered amorphous by subsequent processing such as ion implantation. The amorphous silicon layer 15 should be distinguished from other types of materials known as “porous” silicon in which the silicon layer 15 includes nano-sized holes in its microstructure.

The amorphous silicon layer 15 (and monocrystalline layer 45 (FIG. 5) of the product structure after crystallization as described below) may have a thickness from about 10 nm to about 10 μm or from about 50 nm to about 150 nm. Generally, the amorphous silicon layer 15 (and crystallized layer 45 described below) is a continuous layer that covers the entire surface of the substrate 12.

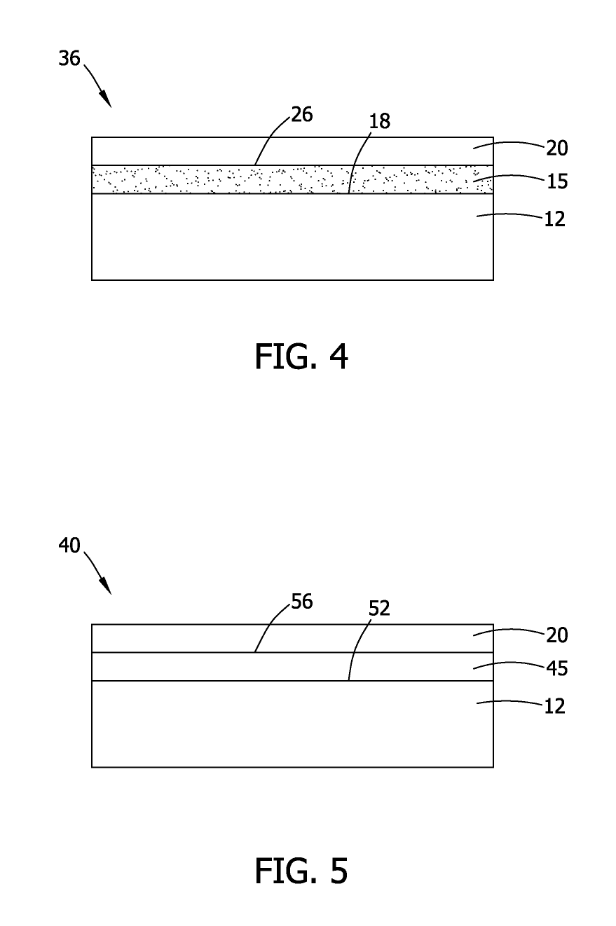

After formation of the amorphous silicon layer 15, a seed wafer 20 (FIG. 4) is bonded to the surface 22 (FIG. 3) of the amorphous silicon layer 15 to form a bonded structure 36. The seed wafer 20 is generally a single crystal silicon wafer and may be a single crystal silicon wafer which has been sliced from a single crystal ingot grown in accordance with conventional Czochralski crystal growing methods. The bonded structure 36 includes the substrate 12, amorphous silicon layer 15 and bonded seed wafer 20 (and any additional surface or intervening layers). In some embodiments, the bonded structure does not include any additional surface or intervening layers and the bonded structure 36 consists of the substrate 12, amorphous silicon layer 15 and bonded seed wafer 20 or consists essentially of the substrate 12, amorphous silicon layer 15 and bonded seed wafer 20 (i.e., contains only negligible additional layers such as a native oxide layer on its surface).

The amorphous silicon layer 15 and seed wafer 20 form a seed-amorphous layer interface 26. The amorphous silicon layer 15 and single crystal silicon seed wafer 20 may be surface treated by contacting the surfaces with a concentrated or dilute HF solution or a HF vapor to remove any native oxide before bonding. The amorphous silicon layer 15 and/or the seed wafer 20 may be cleaned in a chamber with a hydrogen plasma to remove a native oxide and form hydride-terminated surfaces. The two structures are then pressed together and a bond at the bond interface 26 is formed there-between.

Bonding of the seed wafer 20 to the amorphous silicon layer 15 may be achieved using essentially any technique known in the art, provided the energy employed to achieve formation of the bond interface is sufficient for the seed wafer 20 to initiate crystallization of the amorphous layer 15 during subsequent thermal processing. Typically, however, wafer bonding is achieved by contacting the bonding surfaces at a reduced pressure (e.g., about 50 mTorr (6.7 Pa)) and at room temperature, followed by heating at an elevated temperature (e.g., at least about 200° C., at least about 300° C., at least about 400° C., or even at least about 500° C.) for a sufficient period of time (e.g., at least about 10 seconds, at least about 1 minute, at least about 15 minutes, at least about 1 hour or even at least about 3 hours). For example, the heating may take place at about 350° C. for about 1 hour. The elevated temperatures cause the formation of covalent bonds between the adjoining surfaces of the seed wafer 20 and the amorphous silicon layer 15, thus solidifying the bond between the seed wafer 20 and the amorphous silicon layer 15.

The bonding surface 22 of the amorphous silicon layer 15 may have a surface roughness (RMS) from about 0.1 nm to about 1.0 nm at a scan size of about 30 μm by about 30 μm prior to bonding the single crystal silicon seed wafer 20 to the amorphous silicon layer 15. A surface roughness (RMS) less than 1.0 nm generally allows the amorphous layer 15 to form a suitable bond with the deposited seed layer 20 such that the seed wafer 20 may initiate crystallization of the amorphous layer 15 during further processing. A surface roughness of at least about 0.1 nm allows bubbles to form at the bond interface to promote separation (e.g., thermal cleave or mechanical cleave) of the seed wafer 20 during or after crystallization.

The bonding surface of the single crystal silicon seed wafer 20 may have a surface roughness (RMS) from about 0.1 nm to about 0.2 nm at a scan size of about 30 μm by about 30 μm. Seed wafer surface roughness of less than about 0.2 nm allows for sufficient bonding contact between the seed wafer 20 and the amorphous silicon layer 15.

Prior to bonding, the bonding surface of the amorphous silicon layer 15 and/or seed wafer 20 may optionally undergo cleaning and/or a brief etching, planarization, or activation to prepare the bonding surfaces for bonding using techniques known in the art. In some embodiments, the bonding surfaces are polished prior to bonding the seed wafer 20 to the amorphous silicon layer 15 to achieve the desired surface roughness. One or more of the following procedures may be used to reduce the surface roughness of the bonding surfaces prior to bonding: (i) planarization by, for example, CMP and/or (ii) cleaning by, for example, a wet chemical cleaning procedure, such as a hydrophilic surface preparation process (e.g., an RCA SC-1 clean process wherein the surfaces are contacted with a solution containing ammonium hydroxide, hydrogen peroxide, and water at a ratio of, for example, 1:2:50 at about 65° C. for about 20 minutes, followed by a deionized water rinse and drying).

In instances in which the surface 22 of the amorphous silicon 15 and/or surface of the crystal silicon seed wafer 20 is activated, the activation process may be a chemical activation or a physical activation. Chemical activation processes may involve exposing one or both of the bonding surfaces to a hydrogen fluoride bath to render the surfaces hydrophobic. Such hydrophobic surfaces may increase the quality of the bond between the amorphous layer 15 and the single crystal silicon seed wafer 20. Physical activation processes may include exposing the bonding surfaces to a hydrogen plasma to render the surfaces hydrophobic.

Generally, the bonded structure 36 includes no more than 3 layers (i.e., consists of the substrate, amorphous silicon layer 15 and seed wafer 20); however, more layers may be used in other embodiments.

After bonding, the bonded structure 36 is annealed in a solid phase epitaxy process (SPE) to crystallize the amorphous silicon layer 15 and generate a monocrystalline silicon device layer 45 (FIG. 5) from the amorphous silicon layer 15. The single crystal silicon wafer 20 acts as a seed for crystallization such that the amorphous layer 15 is crystallized from the seed-amorphous layer interface 26 toward the amorphous layer-substrate interface 18. Without being bound to any particular theory of crystallization, the surface hydrides on the bonding surfaces are believed to desorb to create dangling bonds. The dangling bonds on the two surfaces bond to each other to form a first layer of epitaxial silicon. It is believed that crystallization does is not initiated at the amorphous layer-substrate interface 18, particularly when the bonded structure is annealed at a temperature less than about 580° C. (e.g., from about 500° C. to about 580° C.). However, the methods of the present disclosure should not be limited to a particular mode of crystallization unless stated otherwise.

The resulting crystallized structure 40 includes a device layer-substrate interface 52 and a seed-device layer interface 56. The resulting crystallized bonded structure 40 comprises the substrate 12, monocrystalline silicon device layer 45 and seed wafer 20. In some embodiments, the crystallized bonded structure 40 consists of the substrate 12, monocrystalline silicon device layer 45 and bonded seed wafer 20 or consists essentially of the substrate 12, monocrystalline silicon device layer 45 and bonded seed wafer 20 (i.e., contains only negligible additional layers such as a native oxide layer on its surface).

Crystallization of the amorphous silicon layer may occur upon heating the bonded structure 36 to a temperature between about 500° C. and about 580° C. in a process chamber or furnace. Suitable heating devices include IR lamps and resistor coils. In some embodiments, a millisecond laser anneal is used in which a laser beam scans the seed wafer 20 surface to locally melt the amorphous silicon surface with crystallization occurring along the path of the laser beam. Such laser anneals typically operate from about 600° C. to about 1200° C.

The crystallization anneal occurs generally in an atmosphere inert relative to the bonded structure 36. The anneal may range from about 0.1 second to about 1 hour depending on the temperature used. The length of the anneal may vary depending on the thickness of the amorphous silicon layer 15 and the anneal temperature, with higher temperatures corresponding to shorter anneal times. Crystallization may be confirmed by examining the crystallized layer by a transmission electron microscope. Generally, the rate of crystallization (e.g., within a temperature range between about 400° C. and about 700° C.) is about 0.1 nm/second to about 10 nm/second. The crystallization anneal is performed for a period of time sufficient to fully crystallize the amorphous silicon layer 15 (as determined by the rate of crystallization and thickness of the layer 15).

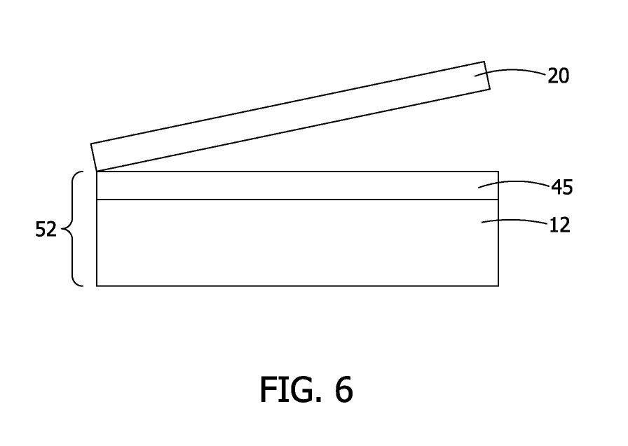

After the amorphous silicon layer 15 (FIG. 4) is crystallized to form a monocrystalline silicon device layer 45 (FIG. 5), the bonded structure 40 may be processed to separate the single crystal silicon seed wafer 20 from the bonded structure and form a layered product structure 52 (FIG. 6) comprising the substrate 12 and the monocrystalline silicon device layer 45. Generally speaking, this fracture may be achieved using techniques known in the art, such as thermally and/or mechanically induced cleaving techniques.

During crystallization of the amorphous silicon layer 15, desorbed hydrides form hydrogen molecules (H₂). The surface roughness of the amorphous silicon layer 15 allows sub-nanometer cavities to be present at the seed-amorphous layer interface 26. These cavities may facilitate nucleation of hydrogen bubbles that accumulate from hydrogen molecules formed from desorbed hydrides during the crystallization anneal. These bubbles may cause stress at the bonding interface and facilitate separation of the single crystal silicon seed wafer 20 from the remaining structure. In some embodiments, the seed wafer 20 separates upon cooling the bonded structure 40 after the crystallization anneal as a result of thermal stress within the bonded structure 40 (i.e., due to different rates of thermal expansion when non-silicon substrates 12 are used) and by hydrogen bubble formation.

In other instances, separation is achieved by annealing the bonded structure 40 at a temperature of at least about 200° C., at least about 300° C., at least about 400° C., at least about 500° C., at least about 600° C., at least about 700° C. or even at least about 800° C. (the temperature being in the range of, for example, about 200° C. to about 800° C., or from about 250° C. to about 650° C.) for a period of at least about 10 seconds, at least about 1 minute, at least about 15 minutes, at least about 1 hour or even at least about 3 hours (with higher temperatures requiring shorter anneal times, and vice versa). The annealing atmosphere may be inert to the bonding structure 40 (e.g., argon or nitrogen) atmosphere or may be ambient.

In some embodiments, separation may be induced or achieved by mechanical force, either alone or in addition to annealing. For instance, the crystallized bonded structure 40 may be placed in a fixture in which mechanical force is applied perpendicular to opposing sides of the bonded structure 40 in order to pull the seed wafer 20 of the bonded structure 40 apart from the bonded structure. According to some methods, suction cups are utilized to apply the mechanical force. The separation of the seed wafer 20 is initiated by applying a mechanical wedge at the edge of the bonded structure at the seed-monocrystalline silicon layer interface 56 in order to initiate propagation of a crack at the interface. The mechanical force applied by the suction cups then pulls the seed structure 20 from the bonded structure, thus forming a layered product structure 52 (FIG. 6). Generally separation is achieved without use of ion implantation.

Referring to FIG. 6, upon separation, two structures are formed. The first structure generally corresponds to the single crystal silicon seed wafer 20 and the second structure is a layered product structure 52 including the substrate 12 and the monocrystalline silicon device layer 45. Generally, the cleaved silicon seed wafer 20 has the same thickness as the wafer 20 before bonding. In this regard, a residual amount of seed wafer 20 may stay attached to the product structure 52 that may be subsequently removed by further processing (e.g., polishing). In this regard, as used herein the “device layer” generally refers to a layer which is suitable for further processing and production of electronic devices and should not be considered in a limiting sense.

After separation, the cleaved seed wafer 20 may be reused by bonding to a second structure formed by depositing a second amorphous silicon layer on a second substrate. The second bonded structure may be annealed to crystallize the amorphous silicon layer and generate a monocrystalline silicon layer from the second amorphous silicon layer. The seed wafer may again be cleaved and reused in additional cycles (e.g., 2, 3, 4 or 5 or more cycles). The seed wafer may be processed before reuse (e.g., cleaning and/or surface roughness reduction by polishing).

Compared to conventional methods for preparing layered semiconductor structures, the methods of the present disclosure have several advantages. By crystallizing the amorphous silicon layer 15 (FIG. 4) to form a monocrystalline silicon device layer 45 (FIG. 5), the time and cost to produce the layered semiconductor structure 52 may be reduced relative to layer transfer methods. In embodiments in which the surface roughness (RMS) of the bonding surface 22 of the amorphous silicon layer 15 is less than 1.0 nm at a scan size of about 30 μm by about 30 μm, the amorphous layer 15 may form a relatively strong bond with the seed wafer 20 to promote crystallization of the amorphous layer 15 from the seed wafer 20. In embodiments in which the bonding surface 22 of the amorphous silicon layer 15 is at least about 0.1 nm at a scan size of about 30 μm by about 30 μm, sufficient bubbles form at the bonded interface to promote separation of the seed wafer 20 upon crystallization. In embodiments in which the bonding surface of the single crystal silicon seed wafer 20 is less than about 0.2 nm at a scan size of 30 μm×30 μm bonding contact between the seed wafer 20 and the amorphous silicon layer 15 may be improved to promote crystallization of the amorphous layer 15 from the seed wafer 20. In embodiments in which the surface 22 of the amorphous silicon layer 15 and/or surface of the crystal silicon seed wafer 20 are rendered hydrophobic before bonding, the quality of the bond between the amorphous layer 15 and single crystal silicon seed wafer 20 may be improved.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiments thereof, the articles “a”, “an”, “the” and “said” are intended to mean that there are one or more of the elements. The terms “comprising,” “including,” “containing” and “having” are intended to be inclusive and mean that there may be additional elements other than the listed elements. The use of terms indicating a particular orientation (e.g., “top”, “bottom”, “side”, etc.) is for convenience of description and does not require any particular orientation of the item described.

As various changes could be made in the above constructions and methods without departing from the scope of the disclosure, it is intended that all matter contained in the above description and shown in the accompanying drawings shall be interpreted as illustrative and not in a limiting sense.

What is claimed is:

1. A method for preparing a layered semiconductor structure having a monocrystalline silicon device layer, the method comprising:
depositing an amorphous silicon layer on a substrate, the amorphous silicon layer and substrate forming an amorphous layer-substrate interface;
bonding a single crystal silicon seed wafer on the amorphous silicon layer to form a bonded structure, the single crystal silicon seed wafer and amorphous silicon layer forming a seed-amorphous layer interface;
annealing the bonded structure to crystallize the amorphous silicon layer and generate a monocrystalline silicon device layer from the amorphous silicon layer; and
cleaving the bonded structure to separate the single crystal silicon seed wafer from the bonded structure and form a layered product structure comprising the substrate and the monocrystalline silicon device layer.

2. The method as set forth in claim 1 wherein the amorphous silicon layer is crystallized from the seed-amorphous layer interface toward the amorphous layer-substrate interface.

3. The method as set forth in claim 1 wherein the substrate is selected from the group consisting of a silicon wafer, quartz, sapphire, ceramics, glass, germanium, silicon germanium, gallium nitride and aluminum nitride.

4. The method as set forth in claim 1 wherein the amorphous silicon layer has a bonding surface, the bonding surface having a surface roughness from about 0.1 nm to about 1.0 nm at a scan size of about 30 μm by about 30 μm prior to bonding the single crystal silicon seed wafer on the amorphous silicon layer to form the bonded structure.

5. The method a set forth in claim 1 wherein the single crystal silicon seed wafer has a bonding surface, the bonding surface having a surface roughness from about 0.1 nm to about 0.2 nm at a scan size of about 30 μm by about 30 μm prior to bonding the single crystal silicon seed wafer on the amorphous silicon layer to form the bonded structure.

6. The method as set forth in claim 1 wherein the amorphous silicon wafer has a bonding surface and the single crystal silicon seed wafer has a bonding surface, the method comprising activating the surfaces to render the surfaces hydrophobic prior to bonding the single crystal silicon seed wafer to the amorphous silicon layer to form the bonded structure.

7. The method as set forth in claim 1 wherein the amorphous silicon layer is a first amorphous silicon layer, the substrate is a first substrate, the bonded structure is a first bonded structure and the layered product structure is a first layered product structure, the method comprising:
depositing a second amorphous silicon layer on a second substrate;
bonding the cleaved single crystal silicon seed wafer on the second amorphous silicon layer to form a second bonded structure, the second single crystal silicon seed wafer and second amorphous silicon layer forming a seed-amorphous layer interface;
annealing the second bonded structure to crystallize the amorphous silicon layer and generate a monocrystalline silicon layer from the second amorphous silicon layer; and
cleaving the second bonded structure to separate the single crystal silicon seed wafer from the bonded structure and form a second layered product structure comprising the second substrate and the monocrystalline silicon layer.

8. The method as set forth claim 1 wherein the amorphous silicon layer is deposited by chemical vapor deposition.

9. The method as set forth in claim 1 wherein the amorphous silicon layer and/or monocrystalline silicon layer have a thickness of from about 10 nm to about 10 μm.

10. The method as set forth in claim 1 wherein the amorphous silicon layer and/or monocrystalline silicon layer have a thickness of from about 50 nm to about 150 nm.

11. The method as set forth in claim 1 wherein the bonded structure is cooled after annealing, the bonded structure cleaving during cooling due to thermal stress within the bonded structure.

12. The method as set forth in claim 1 wherein the amorphous silicon layer is a continuous layer.

13. The method as set forth in claim 1 wherein the bonded structure is annealed at a temperature from about 500° C. to about 580° C. to crystallize the amorphous silicon layer and generate a monocrystalline silicon device layer from the amorphous silicon layer.

14. A bonded structure comprising:
a substrate selected from the group consisting of a silicon wafer, quartz, sapphire, ceramics, glass, germanium, silicon germanium, gallium nitride and aluminum nitride.
a single crystal silicon seed wafer; and
an amorphous silicon layer disposed between the substrate and the single crystal silicon seed wafer, the amorphous silicon layer and substrate forming an amorphous layer-substrate interface, the single crystal silicon seed wafer and amorphous silicon layer forming a seed-amorphous layer interface.

15. The bonded structure as set forth in claim 14 wherein the amorphous silicon layer has a thickness of from about 10 nm to about 10 μm.

16. The bonded structure as set forth in claim 14 wherein the amorphous silicon layer has a thickness of from about 50 nm to about 150 nm.

17. A bonded structure comprising:
a substrate selected from the group consisting of a silicon wafer, quartz, sapphire, ceramics, glass, germanium, silicon germanium, gallium nitride and aluminum nitride;
a single crystal silicon seed wafer; and
a monocrystalline silicon device layer disposed between the substrate and the single crystal silicon seed wafer, the monocrystalline silicon device layer and substrate forming a device layer-substrate interface, the single crystal silicon seed wafer and monocrystalline silicon device layer forming a seed-device layer interface.

18. The bonded structure as set forth in claim 17 wherein the monocrystalline silicon device layer has a thickness of from about 10 nm to about 10 μm.
